(19) United States
(12) Patent Application Publication
(10) Pub. No.: US 2015/0301525 A1
(43) Pub. Date: Oct. 22, 2015

(54) METHOD FOR PRINTED CIRCUIT BOARD PANELIZATION

(71) Applicant: PCB:NG, Inc., Brooklyn, NY (US)

(72) Inventors: Jonathan Hirschman, Brooklyn, NY (US); Petro Bakhirev, Brooklyn, NY (US); James Graham, Brooklyn, NY (US)

(21) Appl. No.: 14/587,820

(22) Filed: Dec. 31, 2014

Related U.S. Application Data
(60) Provisional application No. 61/922,103, filed on Dec. 31, 2013.

(51) Int. Cl. G05B 19/418; H05K 3/00; G06F 17/50

(52) U.S. Cl. CPC G05B 19/41865; G06F 17/5068; H05K 3/0005; G05B 2219/45035

(57) ABSTRACT

A method includes determining a single standard batch quantity for all printed circuit boards designs to be considered for placement on one or more panels, determining a selection preference based on at least a first characteristic for each of the printed circuit board designs, for each printed circuit board design in order of selection preference, assigning quantities of printed circuit board designs that satisfy a second characteristic to different batches, the quantities determined by the standard batch quantity divided by each whole integer divisor, and selecting one or more batches for panel placement according to a design cost characteristic.

### BACKGROUND

A major factor of the cost of Printed Circuit Board Assembly (“PCBA”) is the difficulty of the selection, configuration and orientation of multiple Printed Circuit Board (“PCB”) designs into one aggregated array, and the configuration and orientation of such an array onto a PCB panel. This process of fitting PCBs, either one or more disparate designs, into arrays, and such arrays into panels, is typically referred to as panelization. A panel refers to a connected matrix of one or more PCB designs that are built in a single sheet by a PCB vendor.

Although most electronic device assemblers receive panels from their clients, or will, in some cases, manufacture a panel containing arrays of one or more disparate designs, according to client specifications, it is important to consider panel design in any optimization efforts in order to insure that the lowest cost of assembly is achieved. Efficient aggregated layout of arrays of multiple client PCB designs may lead to lower costs of assembly, and to lower minimum order quantities “MOQ”, sometimes also termed “runs”. However, finding an optimal configuration of aggregated arrays of multiple client PCB designs is a non-trivial task for some of the enumerated reasons:
1). Every client may require a different number of assembled PCBs such that a combination of designs may not fit on a single panel;
2). Aggregated designs may require different types and numbers of components, known as a Bill Of Materials (“BOM”) for assembly such that a combination of designs may exceed certain operational parameters of the assembly equipment;
3). Disparate designs may have different PCB construction characteristics such that placing such designs in physical proximity to each other may cause quality issues;
4). Clients may require differing fulfillment dates.

Typically, a person wanting to perform a panelization optimization, using multiple aggregated designs, has to run a different analysis for each of the combinations of client BOMs, for each of the clients delivery schedules, for each of the client's desired assembly quantities, and for each of the multiple differing physical characteristics. Because of all of the possible combinations, this approach can be very time consuming and the assembler may never achieve an optimal solution. Given the above, a need exists in the art for a method of panelization that can minimize some of the shortcomings found in the prior art.

### SUMMARY

The disclosed embodiments are directed to a method including determining a single standard batch quantity for all printed circuit boards designs to be considered for placement on one or more panels, determining a selection preference based on at least a first characteristic for each of the printed circuit board designs, for each printed circuit board design in order of selection preference, assigning quantities of printed circuit board designs that satisfy a second characteristic to different batches, the quantities determined by the standard batch quantity divided by each whole integer divisor, and selecting one or more batches for panel placement according to a design cost characteristic.

According to one or more aspects of the disclosed embodiments, the standard batch quantity comprises a highly composite number.

Some aspects of the disclosed embodiments include determining the first characteristic from an area, number of unique components, and an elapsed time of an order for the printed circuit board designs.

Certain aspects of the disclosed embodiments include determining the second characteristic from bill of material information for the quantity of a printed circuit board design.

At least one aspect of the disclosed embodiments includes determining the second characteristic from a reel capacity of a machine for assembling the one or more panels.

One or more aspects of the disclosed embodiments include determining the second characteristic from a tray holder capacity of a machine for assembling the one or more panels.

Some aspects of the disclosed embodiments may also include determining the second characteristic from a tube feeder capacity of a machine for assembling the one or more panels.

Certain aspects of the disclosed embodiments may also include determining the second characteristic from a tray space capacity of a machine for assembling the one or more panels.

At least one aspect of the disclosed embodiments includes determining the second characteristic from a panel area occupied by the quantity of the printed circuit board design.

One or more aspects of the disclosed embodiments may also include determining the design cost characteristic from an average panel expense, a panel utilization percentage, and a panel area.

The disclosed embodiments may also include determining a copper density value for each layer of each printed circuit board design of the batches selected for panel placement, and sorting the printed circuit board designs of the batches selected for panel placement according to a copper gradation scheme.

The disclosed embodiments are further directed to an apparatus having a processor and a memory including computer program code configured to, with the processor, cause the apparatus to determine a single standard batch quantity for all printed circuit boards designs to be considered for placement on one or more panels, determine a selection preference based on at least a first characteristic for each of the printed circuit board designs, for each printed circuit board design in order of selection preference, assign quantities of printed circuit board designs that satisfy a second characteristic to different batches, the quantities determined by the standard batch quantity divided by each whole integer divisor, and select one or more batches for panel placement according to a design cost characteristic.

In some aspects of the disclosed embodiments, the standard batch quantity comprises a highly composite number.

In certain aspects of the disclosed embodiments, the first characteristic is determined from an area, number of unique components, and an elapsed time of an order for the printed circuit boards designs.

In at least one aspect of the disclosed embodiments, the second characteristic is based on bill of material information for the quantity of a printed circuit board design.

In one or more aspects of the disclosed embodiments, the second characteristic is based on a reel capacity of a machine for assembling the one or more panels.

In some aspects of the disclosed embodiments, the second characteristic is based on a tray holder capacity of a machine for assembling the one or more panels.

In certain aspects of the disclosed embodiments, the second characteristic is based on a tube feeder capacity of a machine for assembling the one or more panels.

In at least one aspect of the disclosed embodiments, the second characteristic is based on a tray space capacity of a machine for assembling the one or more panels.

In one or more aspects of the disclosed embodiments, the second characteristic is determined from a panel area occupied by the quantity of the printed circuit board design.

According to some aspects of the disclosed embodiments, the design cost characteristic is determined from an average panel expense, a panel utilization percentage, and a panel area.

In at least one aspect of the disclosed embodiments, the memory including computer program code is configured to, with the processor, further cause the apparatus to determine a copper density value for each layer of each printed circuit board design of the batches selected for panel placement, and sort the printed circuit board designs of the batches selected for panel placement according to a copper gradation scheme.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments. In the drawings:

FIG. 1 is a prior art, exemplary PCB panel, with exemplary PCB designs arranged within;

FIG. 2 is a prior art, exemplary PCB panel, with exemplary PCB designs arranged within;

FIG. 3 is a prior art, exemplary PCB panel, with exemplary PCB designs arranged within;

FIG. 4 is a prior art, exemplary PCB panel, with exemplary PCB designs arranged within;

FIG. 5 is a prior art, exemplary PCB panel, with exemplary PCB designs arranged within;

FIG. 6 is a prior art, exemplary representation of a PCB Bill Of Materials;

FIG. 7A is a prior art, exemplary representation of a PCB component supply reel;

FIG. 7B is a prior art, exemplary representation of a PCB component carrier tape;

FIG. 8A is a prior art, exemplary representation of a PCB component supply tray;

FIG. 8B is an exemplary representation of a planar surface holding multiple component types;

FIG. 8C is a prior art, exemplary representation of a PCB component supply tube;

FIG. 9 is a prior art, exemplary representation of PCB copper layers;

FIG. 10 is a prior art, exemplary PCB panel, with exemplary PCB designs arranged within;

FIG. 11 is a flowchart generally representing an exemplary process according to the disclosed embodiments;

FIG. 12 is a flowchart generally representing an exemplary process according to the disclosed embodiments;

FIG. 13 is a flowchart generally representing an exemplary process according to the disclosed embodiments;

FIG. 14 is an exemplary PCB panel, with exemplary copper gradation scheme illustrated according to the disclosed embodiments;

FIG. 15 is a flowchart generally representing an exemplary process according to the disclosed embodiments; and

FIG. 16 shows a block diagram of a computing system that may be used to practice aspects of the disclosed embodiments.

### DETAILED DESCRIPTION

It is believed that the disclosed embodiments will be better understood from a consideration of the following description in conjunction with the drawing figure(s).

In the following detailed description, numerous specific details are set forth to provide a full understanding of the present disclosure. It will be apparent, however, to one ordinarily skilled in the art that the embodiments of the present disclosure may be practiced without some of these specific details. In other instances, well-known structures and techniques have not been shown in detail so as not to obscure the disclosure.

In at least one of the disclosed embodiments, a PCB panel optimizing method comprises a procedure that determines an optimal configuration of PCB designs to form an aggregated array, to configure one or more aggregated arrays on a panel or across multiple panels, which maximizes the efficiency of subsequent PCBA operations, minimizes PCB fabrication costs, and prevents proximally located PCB designs on a panel from causing structurally related fabrication issues (such as physical warping). PCBA operations are considered to be optimal for a PCB panel if there is no requirement to change the configuration of the assembly apparatus during assembly operations. One such configuration change, which typically requires pausing assembly operations, involves adding to, removing from or otherwise altering the component supplies that the assembly apparatus employs during assembly operations.

Although the disclosed embodiments will be discussed in relation to a web-based software tool, the disclosed embodiments can be utilized in one or more stand-alone computer systems, networked computer systems, or other hardware devices that can execute the disclosed panelization procedure.

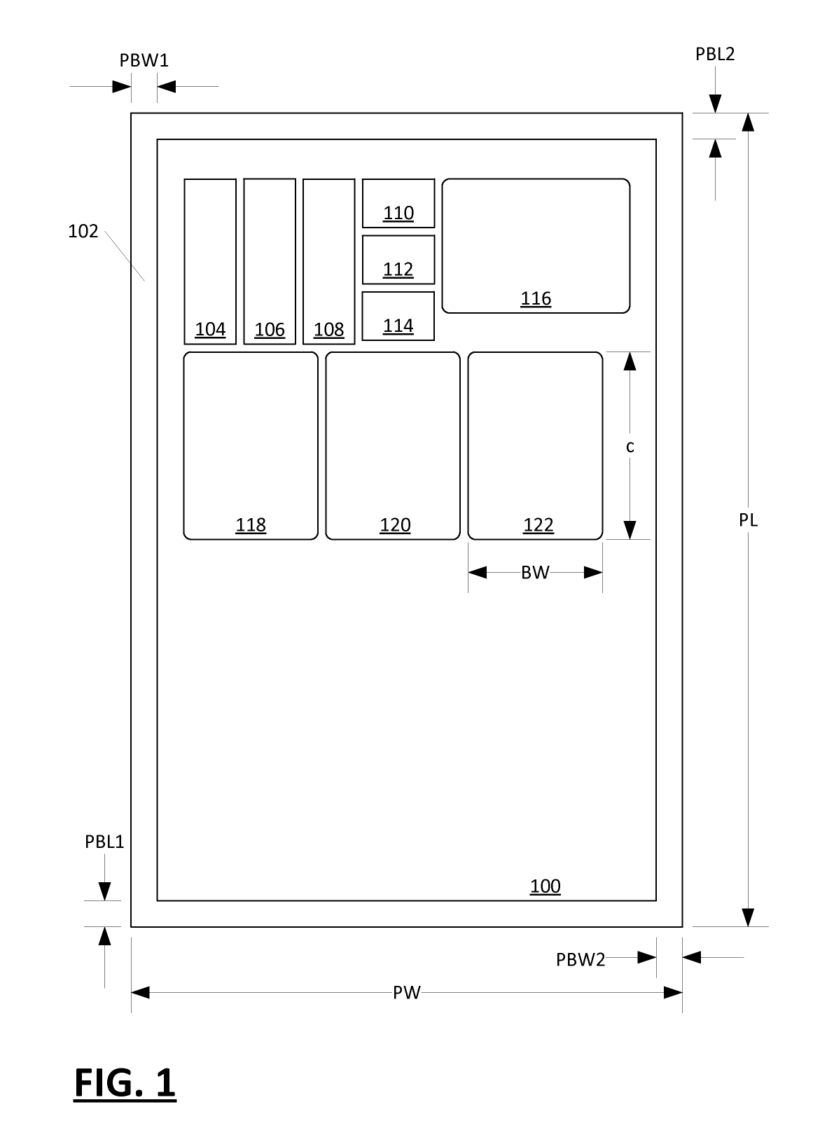

Referring now to FIG. 1, there is shown a prior art panel 100, having a border 102. As well known to one of ordinary skill in the art, PCB panels are often created with borders to facilitate workholding for later assembly. Thus, panel 100 has several dimensional specifications, including the Panel Length (“PL”), the Panel Width (“PW”), the Panel Border Width 1 (“PBW1”), the Panel Border Width 2 (“PBW2”), the Panel Border Length 1 (“PBL1”) and the Panel Border Length 2 (“PBL2”). There is also shown a plurality of PCBs 104-122 within panel 100. The PCBs dimensional specifications include the Board Length (“BL”) and the Board Width (“BW”) The panel and PCB dimensional specifications may be input manually, determined from PCB design files, or may be determined from any number of suitable sources. One or more of the dimensions described are used as input information for the panelization method of the disclosed embodiments. Panel 100 can be manufactured from any one of a number of different materials used to manufacture PCBs as known in the art.

The percentage of area of a PCB panel that is devoted to actual PCBs may be termed the Panel Utilization Percentage (“PUP”). The PUP may be expressed, where the number of panelized PCBs=n, and the number of iterations of each PCB=d:

PUP=(((BL₁×BW₁)×d)+((BL₂×BW₂)×d)+((BL₃×BW₃)×d)+ . . . ((BLₙ×BWₙ)×d)))))/((PW−(PBW1+PBW2))×((PL−(PBL1+PBL2))

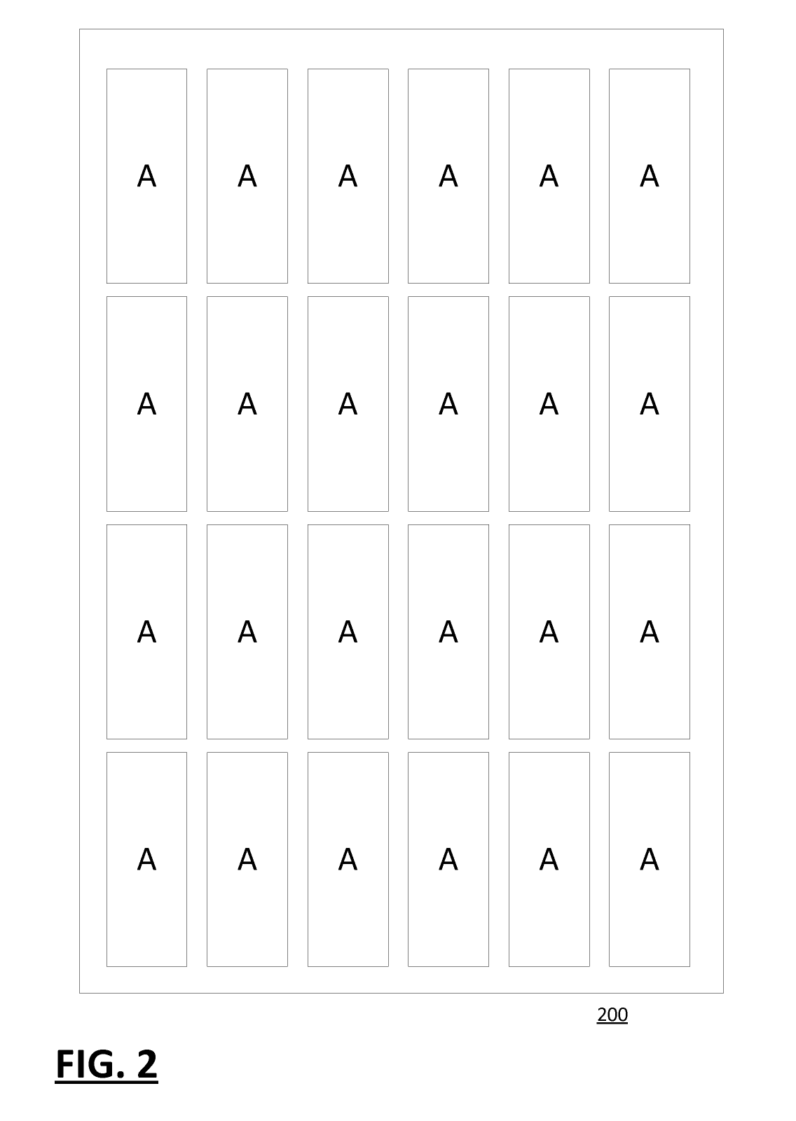

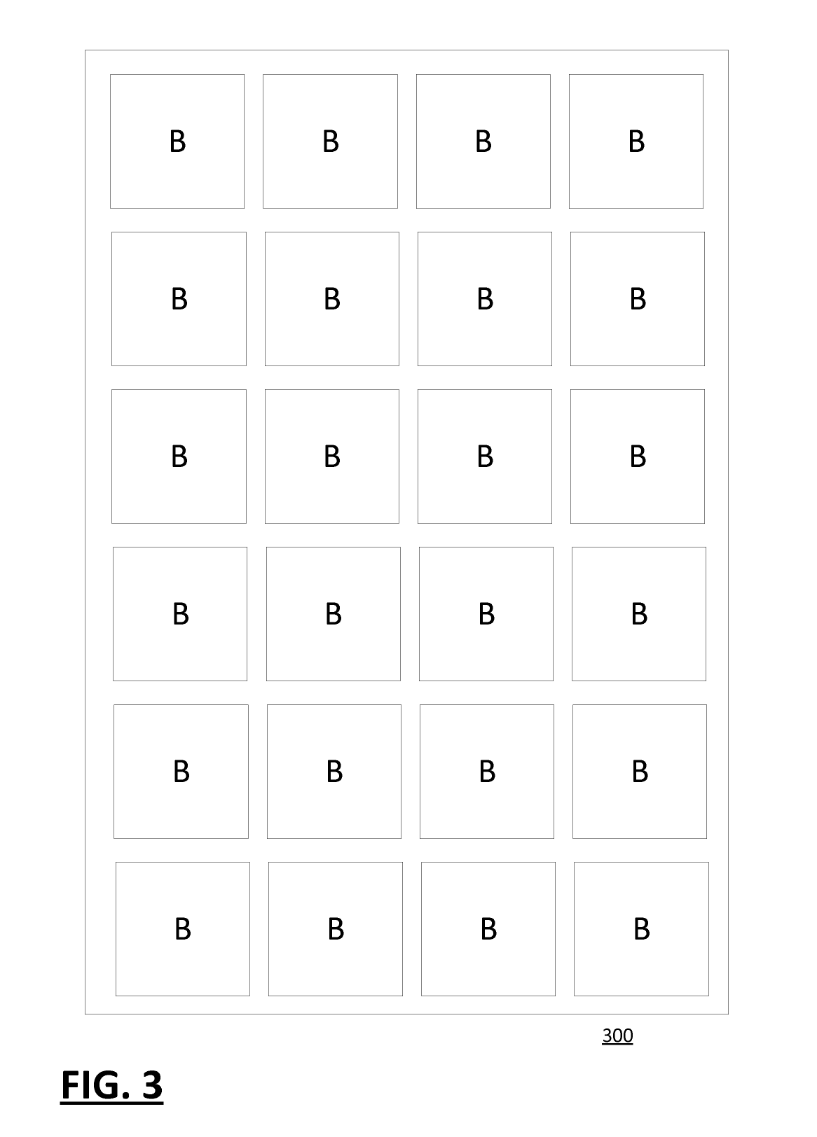

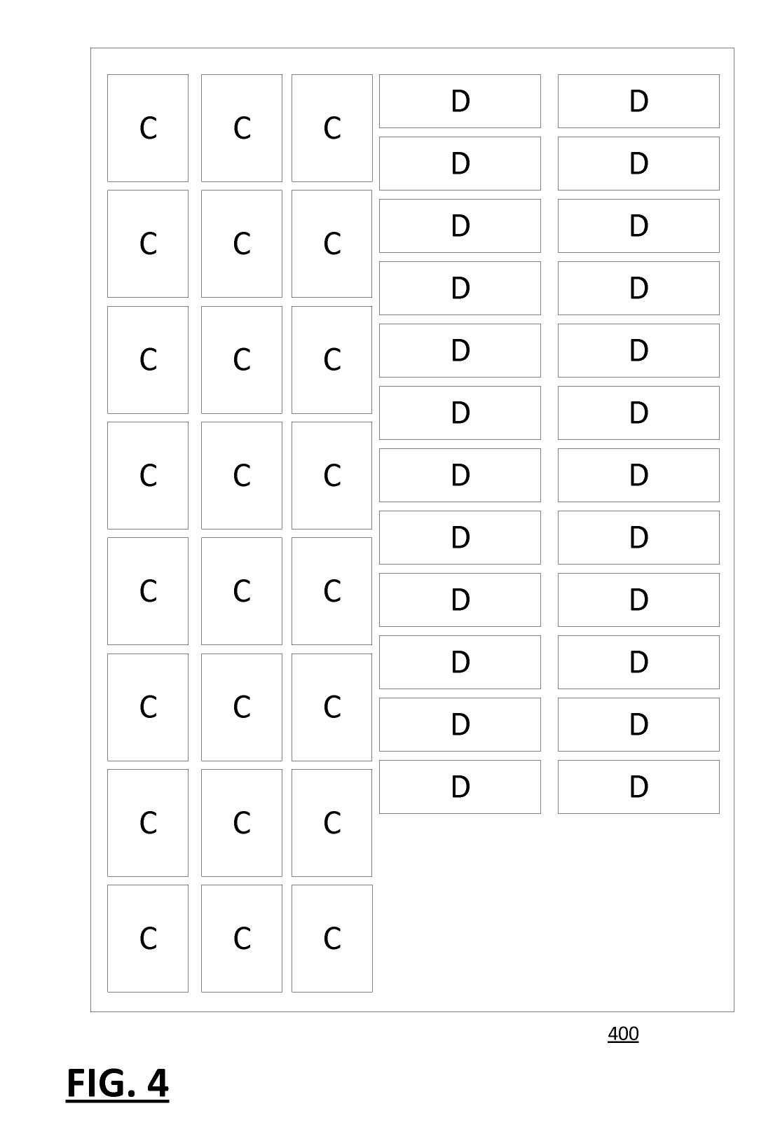

In FIG. 2, there is shown a panel 200, which contains an array composed of 24 copies of PCB Design A. Likewise, in FIG. 3, there is shown a prior art panel 300 which contains an array composed of 24 copies of PCB Design B. FIG. 4 illustrated yet another prior art panel 400, which contains two arrays of 24, each composed of PCB Design C and PCB Design D. Panels 200, 300 and 400 are drawn to the same scale.

As is well known in the art, the expense of panel fabrication may be mitigated if multiple copies of a PCB panel are fabricated during the same production run. The Panel Copy Expense (“PCE”) of a PCB panel is typically a small fraction of First Panel Expense (“FPE”).

Thus, the Average Panel Expense (“APE”) of a number of PCB panels, all alike, for panel quantity n may be expressed as:

APE=(FPE+(PCE×(n−1)))/n

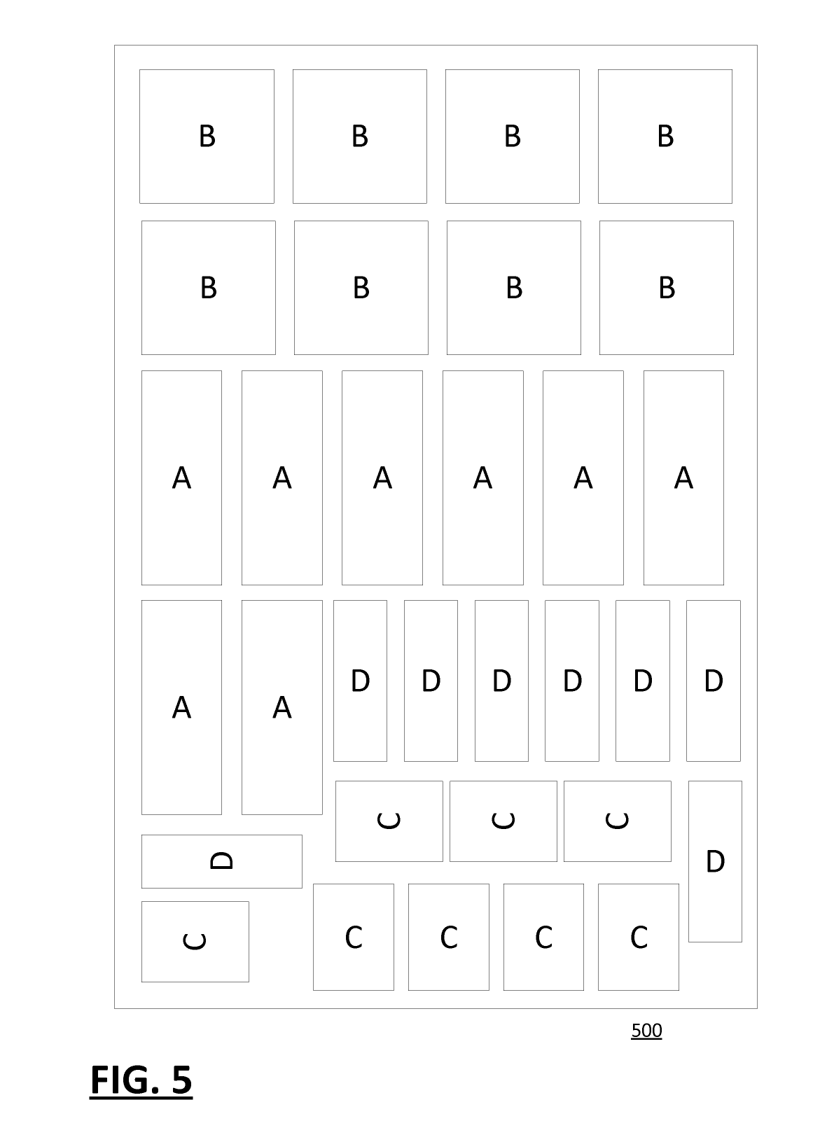

Referring now to FIG. 5, there is shown a prior art panel 500, again drawn to the same scale as Panels 200, 300 and 400. Panel 500 contains four arrays of eight copies, each, of PCB Designs A, B, C and D. For the case illustrated by FIGS. 2-4, that is, having 24 copies of PCB Designs A, B, C and D fabricated with the panelization designs shown in those figures, and with an FPE of 4x, and a PCE of x, the Average Panel Expense of fabrication for each of the four designs would be:

APE=(4x+(x×(1−1)/1

APE=(4x+0)/1

APE=4x

However, for the case illustrated by FIG. 5, where eight copies of each design are contained within a single panel, and requiring three copies of Panel 500 to be fabricated, the Average Panel Expense of fabrication for each of the four designs would be:

APE=(4x+(x×(3−1)/3

APE=(4x+2x)/3

APE=2x

Thus, panelizing the same PCB designs, but in the fashion shown in FIG. 5, reduces the cost of fabrication by half. According to one or more of the disclosed embodiments, PCBs may be ordered in the same batch quantity for each design. Also according to the disclosed embodiments, PCBs may be ordered in batches corresponding to a given Highly Composite Number (“HCN”), which is also the Standard Batch Quantity. HCNs are characterized by having more divisors than any smaller positive integer. Examples include the numbers 1, 2, 4, 6, 12, 24, 36, 48, and 60. In the examples illustrated in FIGS. 2-5, that number is 24, which is divisible by 1, 2, 3, 4, 6, 8, 12 and 24. While the disclosed embodiments are illustrated using the HCN of 24, it should be understood that any suitable HCN may be utilized. Thus, disparate PCB designs may be aggregated according to, and across the most cost-effective number of panels.

Furthermore, the Design Cost Efficiency (“DCE”) of fabricating various sets of PCB designs across a number of panels may be expressed as:

DCE=(APE×(1−PUP))/(PW×PL)

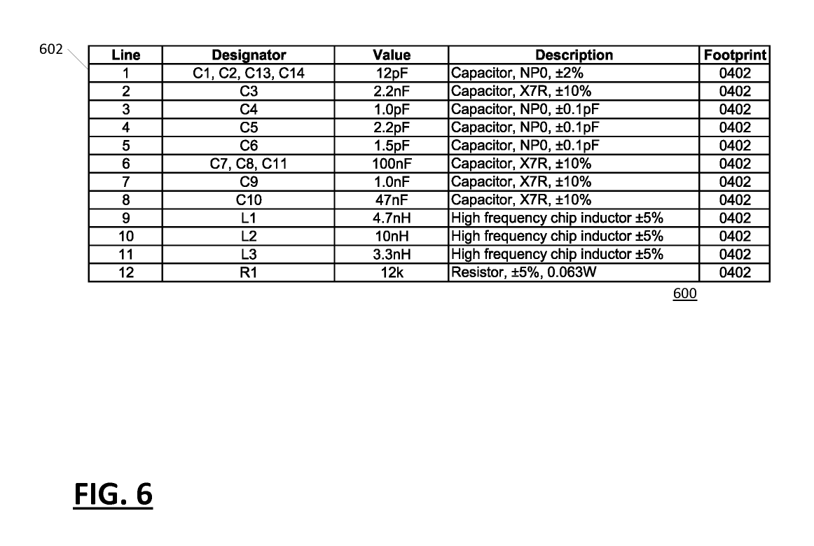

Referring now to FIG. 6, there is shown a prior art tabular representation 600 of a typical BOM. Actual BOM data may be provided in such formats as, but not limited to, Comma Separated Value text (“CSV”), Extensible Markup Language (“XML”) and JavaScript Object Notation (“JSON”). Table 600 includes a plurality of lines 202, each representing a unique type of component specified for placement on a given PCB. The total number of line items of a BOM is referred to as “Uniques”; BOM 600 compromises 12 Uniques. BOM data is not, as known in the art, standardized. BOM data may include additional fields, or omit some of the fields shown in table 600.

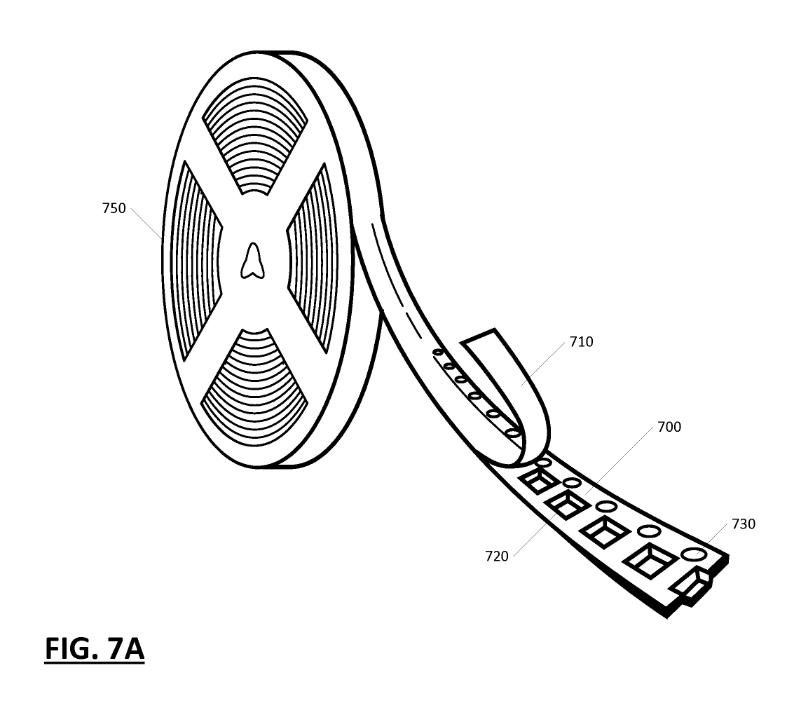

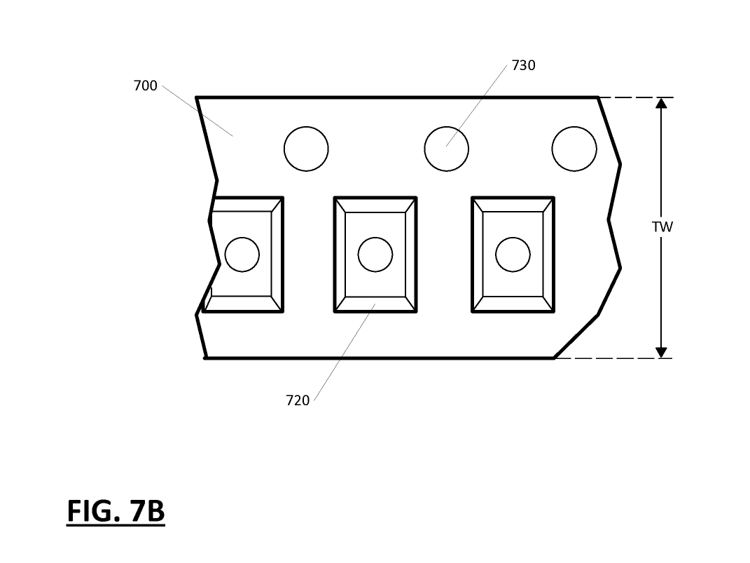

FIG. 7A illustrates a prior art supply reel 750, upon which is wound a plastic or paper carrier tape 700. Carrier tape 700 is provided with successive embossments or pockets 720. Each embossment 720 carries a separate component, not shown, and is covered by a continuous strip or top cover tape 710. The carrier tape includes regularly spaced sprocket holes 720 along one or both edges to allow the tape to be fed by the gears/sprockets of automated component placement apparatus used for PCBA, for example, “Pick and Place machines”.

FIG. 7B illustrates another view of prior art carrier tape 700. It is well known in the art that carrier tapes are specified in standard Tape Widths (“TW”). Moreover, PCBA machines may accommodate a plurality of tape widths, and of supply reels. PCBA machines have a finite capability to accommodate a number of supply reels at any given time, which varies between model and manufacturer. As known in the art, PCBA machines are typically specified in terms of their Reel Capacity (“RC”) by the maximum number of supply reels that can be fitted at one time. The RC may be specified with respect to the smallest supply reel width that may be accommodated, for example 4 mm, or may be specified with respect to a typical supply reel width, for example 8 mm.

While a PCBA machine may have a specified Reel Capacity, components are often packaged in carrier tapes of larger Tape Widths, commonly ranging up to 84 mm. Thus, the Component Reel Space Requirement (“CRSR”), for at least one of the disclosed embodiments, for a given component package in carrier tape, may be expressed as:

CRSR=┌(TW/X)┐

where X represents the width used to specify the RC increment for the PCBA machine.

Thus, for a value of X of 8, a component with a TW of 12 mm or 16 mm would have a CRSR of 2; a component with a TW of 44 mm would have a CRSR of 6. The formula for determining CRSR is ultimately specific to a given PCBA machine design, and may be adjusted or altered for various models commonly available. While the disclosed embodiments are illustrated using a value of 8 for X, it should be understood that other values may be utilized.

Furthermore, by applying this formula to each BOM item of a PCB design, the total PCB CRSR (“PCBCRSR”) may be determined. Similarly, in the case of a panel containing multiple PCB designs, the total panel CRSR (“PCRSR”) may likewise be determined by first combining all of the BOM items of the PCB designs contained within the panel into an aggregate BOM, assigning a CRSR value of 0 to duplicated items (e.g., in the case where the same component was used in more than one PCB design), and then performing simple addition of the CRSR value of all line items in the aggregate BOM.

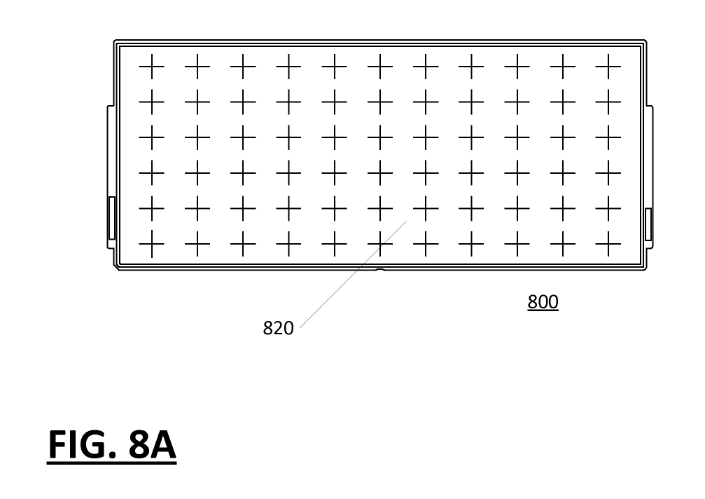

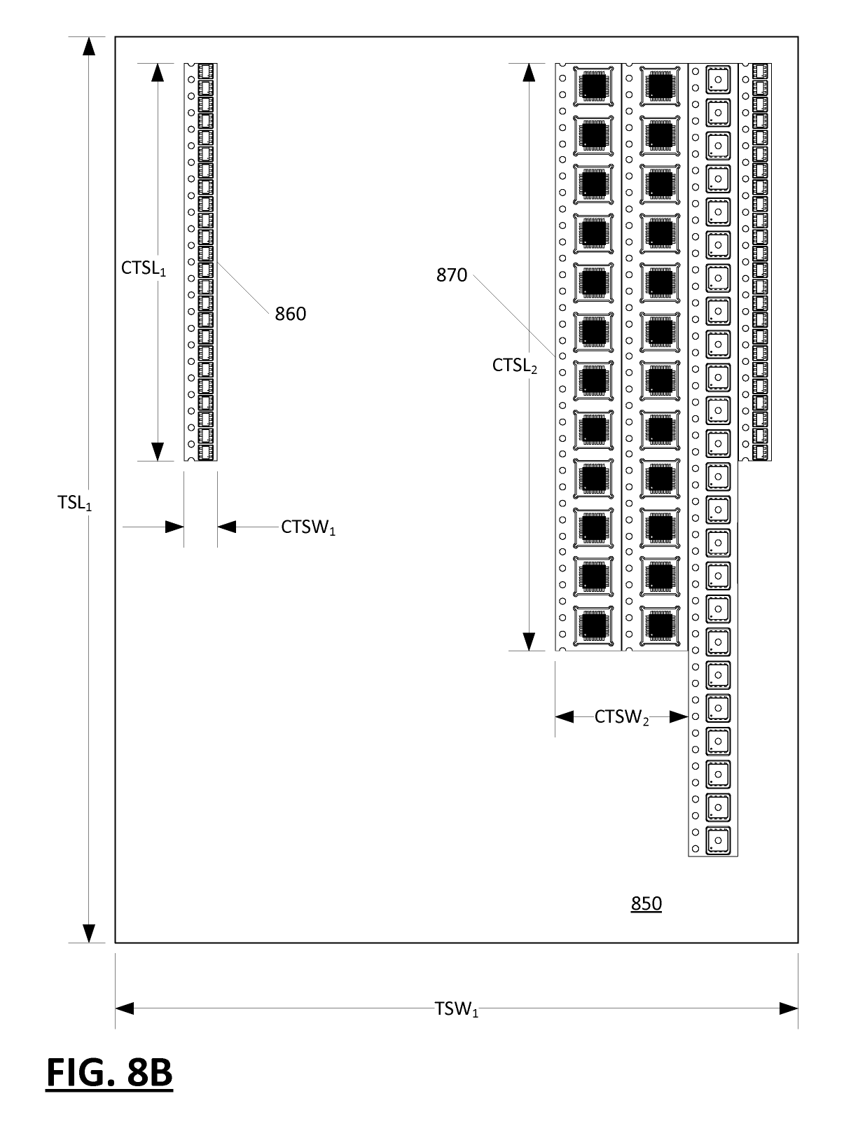

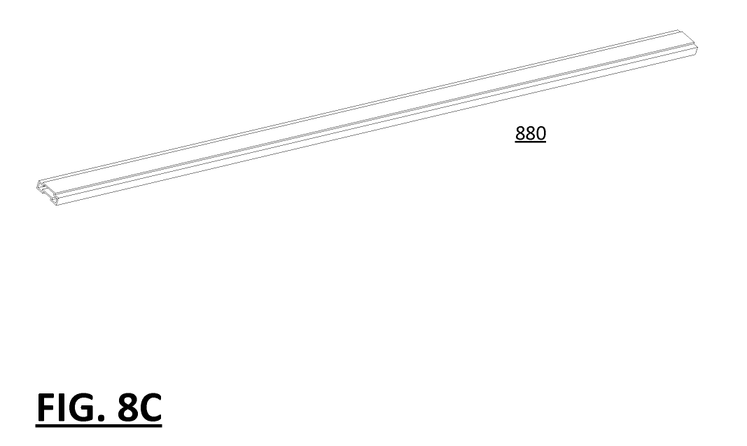

FIG. 8A illustrates a prior art supply tray 800. Supply tray 800 is provided with a matrix of embossments or pockets 820. Each embossment 820 carries a separate component, not shown. Supply tray 800 is designed for use with automated component placement PCBA apparatus. Supply trays, as known in the art, are standardized in terms of dimensions, in accordance with industry standards, and vary only in the size of embossments 820, which is governed by the size of the component stored therein. Therefore, the Component Tray Capacity (“CTC”), or number of components stored within a tray, will vary with actual component physical dimensions.

PCBA machines may have none, one or a plurality of tray holders, (each) in a distinct physical location. This may be expressed as Tray Holder Capacity (“THC”). In at least one of the disclosed embodiments each tray holder may accommodate a single tray of a given component type. Moreover, in the case of PCBA machines with a THC greater than one, multiple tray holders may be configured with the same component type. Additionally, PCBA machines may be equipped with none, one or a plurality of tray feeder apparatus, which will automatically replenish exhausted trays in a distinct physical location. Thus, a given tray holder may accommodate multiple trays (of a single component type), up to the feeder maximum tray capacity (“TFMAX”) of the tray feeder apparatus assigned to a given tray holder.

Thus, the Tray Holder Component Capacity (“THCC”) may be expressed as:

THCC=CTC×(TFMAX+1)

Furthermore, the Total Tray Holder Component Capacity (“TTHCC”), or the maximum number of components that a PCBA machine may accommodate without further operator intervention, may be expressed as, where THC=n:

TTHCC=(CTC₁×(TFMAX₁+1))+(CTC₂×(TFMAX₂+1))+ . . . (CTCₙ×(TFMAXₙ+1))

Thus, given the example of a PCBA machine with two tray holders (e.g., THC=2), each equipped with a tray feeder that accommodates 10 trays (e.g., TFMAX=10), with a component type such that each tray contains 100 components (e.g., CTC₁=100) is assigned to tray holder 1, and with a component type such that each tray contains 50 components (e.g., CTC₂=50), the TTHCC would be:

TTHCC=(100×(10+1))+(50×(10+1))

TTHCC=(1100)+(550)

TTHCC=1650

In some of the disclosed embodiments, trays may not have standardized dimensions, may not be limited to containing single types of components, and may or may not be removable. For example, a tray may simply be a planar surface from which a PCBA machine may access components. PCBA machines may have none, one or a plurality of such trays capable of having components, contained in unreeled sections of carrier tape (“cut tape”), removed from supply reel 750, and mounted upon such trays with various methods. Additionally, trays similar to supply tray 800, but without embossments, and of an arbitrary size, may be employed for the same purpose.

FIG. 8B illustrates another exemplary tray 850. In at least one of the disclosed embodiments, at least one tray may be employed to hold multiple components packaged in cut tape. Each tray has physical dimensions; in the case of tray 850, the Tray Surface Length (“TSL”) and the Tray Surface Width (“TSW”). Trays are considered to be rectangular in this embodiment, but other shapes may be employed in other embodiments.

Cut tape 860, if it holds a unique component type, may be termed a cut tape segment. As in the case of cut tapes 870, multiple pieces of cut tape, if they all contain the same component, are considered to be part of a segment. Additionally, if the pieces of cut tape are non-contiguous, and if such pieces may furthermore be located on the same, or on different trays, as long as they are accessible by a particular PCBA machine, they are considered to be a single cut tape segment. Each cut tape segment may be said to have a Cut Tape Segment Length (“CTSL”), or the aggregate length of all pieces of cut tape containing that component type; similarly, each cut tape segment may also be said to have a Cut Tape Segment Width (“CTSW”).

Thus, in this embodiment, the Total Tray Space Capacity may be expressed as the combined area of all trays available to a particular PCBA machine:

TTSC=(TSL₁×TSW₁)+(TSL₂×TSW₂)+(TSL₃×TSW₃)+ . . . (TSLₙ×TSWₙ)

Additionally, a given component's Tray Space Requirement (“CTSR”) may be expressed as the area required by a cut tape segment, or:

CTSR=CTSL×CTSW

FIG. 8C illustrates a prior art supply tube 880. Supply tube 880 is designed for use with PCBA machines. Supply tubes, as known in the art, are sized according to component dimension, and the number of components within a supply tube. Therefore, the Component Tube Capacity (“CTUC”), or number of components stored within a tube, will vary with actual component physical dimensions.

PCBA machines may have none, one or a plurality of tube feeders, each in a distinct physical location. This may be expressed as Tube Feeder Capacity (“TFC”). Each tube feeder, typically, may accommodate any supply tube of common use, regardless of dimension. Thus, the Tube Feeder Component Capacity (“TFCC”) is equal to the CTUC of a given component.

Furthermore, the Total Tube Feeder Component Capacity (“TTFCC”), or the maximum number of components that a PCBA machine may accommodate without further operator intervention, may be expressed as, where TFC=n:

TTFCC=CTUC₁+CTUC₂+CTUCₙ

Thus, given the example of a PCBA machine with three tube feeders (e.g., TFC=3), the first configured with a component type such that each tube contains 100 components (e.g., CTUC₁=100), the second tube feeder configured with a component type such that each tube contains 50 components (e.g., CTUC₂=50), and the third configured with a component type such that each tube also contains 50 components (e.g., CTUC₃=50), the TTFCC would be:

TTFCC=100+50+50

TTFCC=200

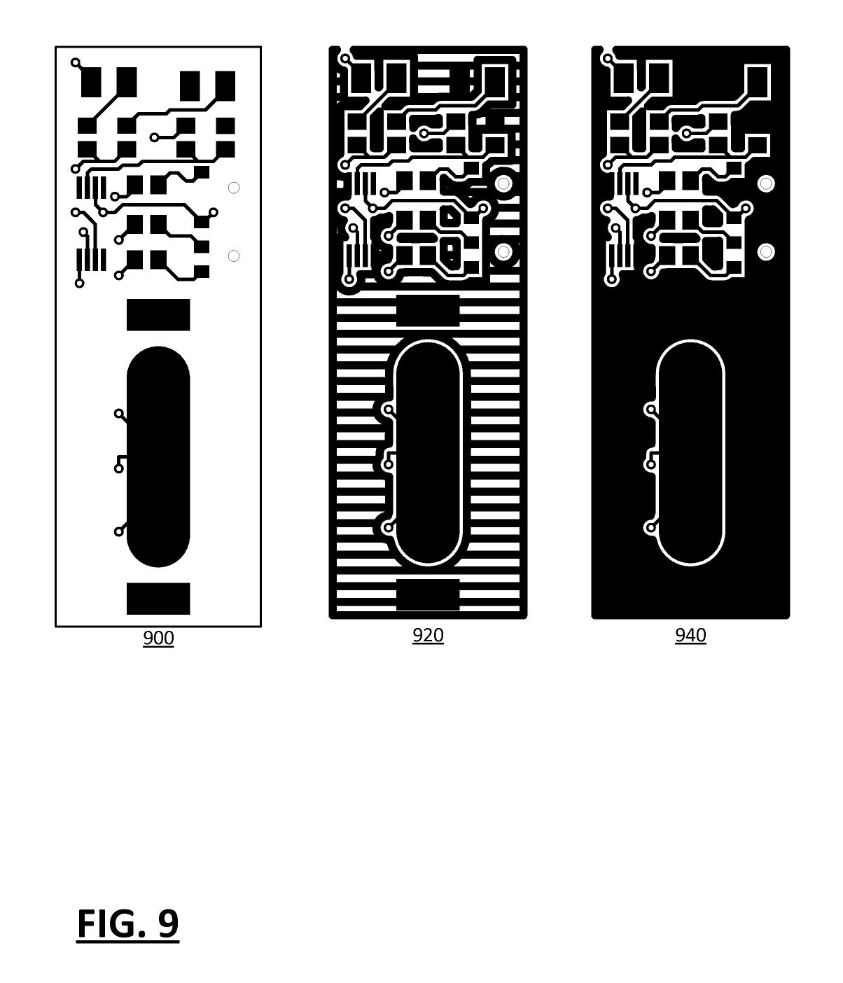

FIG. 9 illustrates three variations of a prior art PCB copper layer 900, 920 and 940 employed in a PCB design. A copper layer refers to, as known in the art, a layer of conductive material, most typically, but not limited to, copper, which may in turn be a component of a PCB. A PCB may be fabricated with one or more copper layers. Each of the copper layers 900, 920 and 940 has a varying Copper Density (“CD”); for example, copper layer 900 has a CD of 25%, copper layer 920 has a CD of 64%, and copper layer 940 has a CD of 82%. A copper layer's area (“CA”) may be determined using methods well known to one of ordinary skill in the art, and may be employed to determine the layer's CD, which may be expressed as:

CD=CA/(BW×BL)

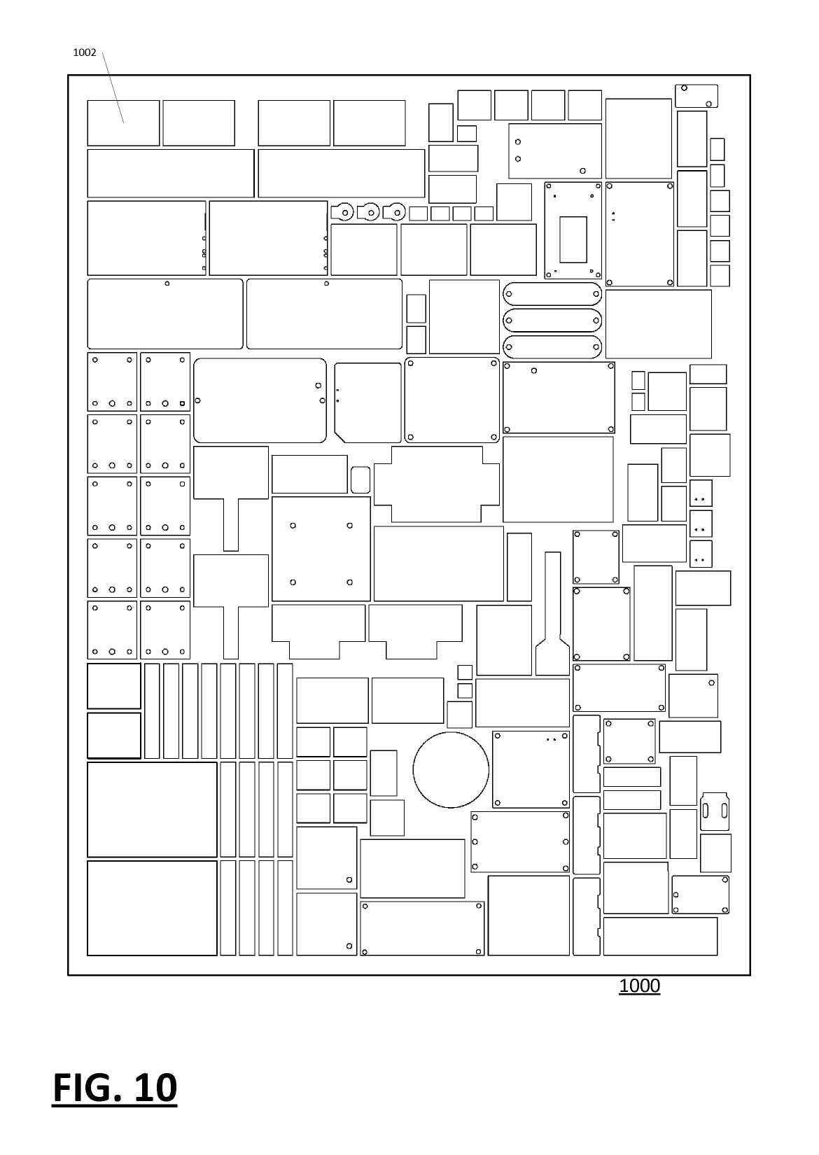

FIG. 10 illustrates a prior art PCB panel 1000 composed of multiple, disparate PCB designs 1002, created using shape-fitting algorithms, tools and techniques which are well known in the art.

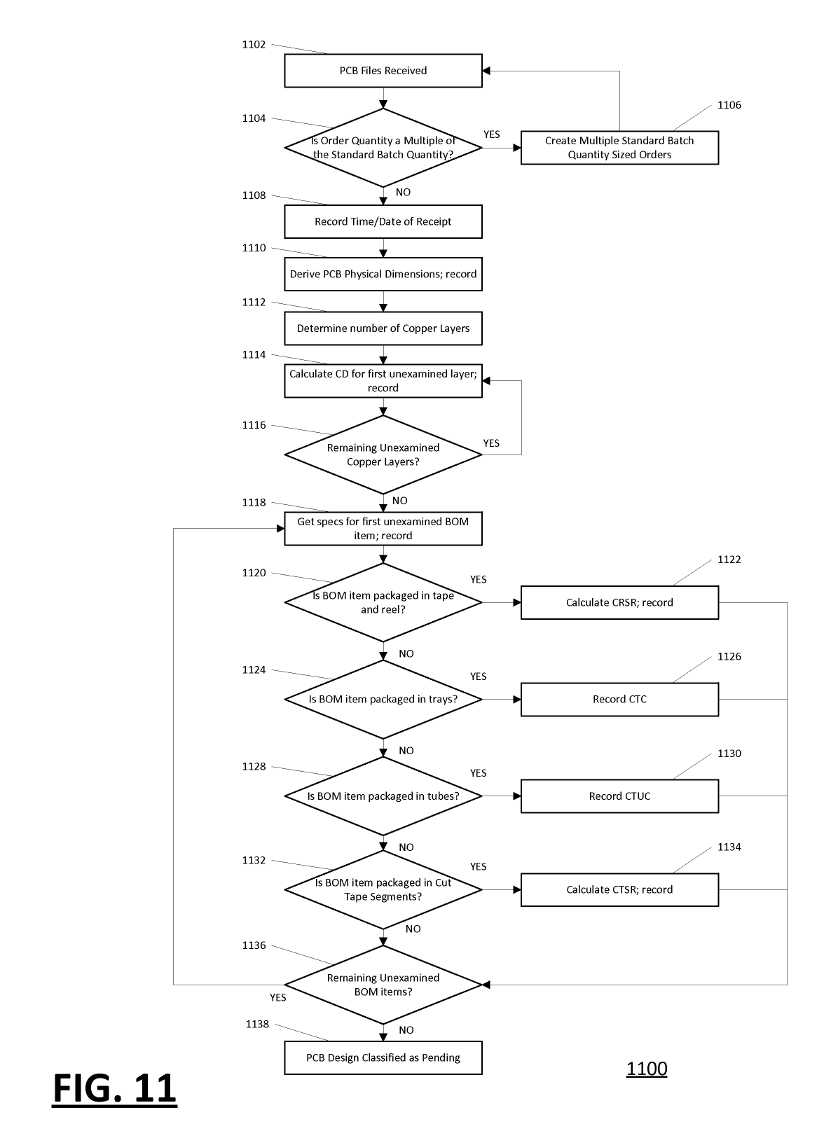

Referring now to FIG. 11, there is shown a flowchart generally representing an exemplary process of the disclosed embodiments. The sample process 1100 highlights some of the operations for collecting and calculating the necessary data for optimal panelization, for example, by determining certain characteristics of PCB designs characterizing.

In block 1102 PCB design files are received from a client. An order quantity may also be received. This may be via electronic transfer, but may also include receiving data stored on physical media by physical transport. The PCB files employed may include those required for PCB fabrication, for example, but not limited to, “Gerber files”, a designation applied to a collection of RS-274X Extended Gerber files and Excellon drill files, and the PCB BOM. Other files may also be employed in the disclosed embodiments. For example, a file format or hierarchical file structure may be utilized that includes a combination of panel dimension data, design dimension data, bill of material data, conductor artwork, drill data, and other data that may be used for fabrication. One example of such a format is ODB++ which is a metafile format that includes physical layout features, drills and other metadata for expressing a PCB design. After the PCB design files are received the routine moves to decision block 1104.

In decision block 1104, it is determined if the order quantity is a multiple of the Standard Batch Quantity; clients are only given the option to order in multiples of the Standard Batch Quantity, which as previously detailed, is an amount equal to a pre-determined HCN. If the order quantity is a multiple of the Standard Batch Quantity, the routine moves to block 1106, wherein the order is automatically resubmitted to block 1102 as multiple smaller orders, each in Standard Batch Quantity. If in decision block 1104 it is determined that the order quantity is the same as the Standard Batch Quantity, the routine moves to block 1108.

In block 1108, the time and date of receipt of the files are recorded. In at least one of the disclosed embodiments, this and all other data and characteristics described as “recorded” may be stored in a database and associated with the submitted PCB files from block 1102, while in other embodiments, it may be stored in a file system along with the submitted PCB files, or as part of a written set of data such as a “job ticket”. The routine moves to block 1110.

In block 1110, the physical dimensions of the PCB design, namely BL and BW, are derived. The dimensions are recorded. The routine moves to block 1112.

In block 1112, the number of copper layers present in a PCB design are determined. The routine moves to block 1114, where the CD is calculated for the first unexamined copper layer of the PCB design, and recorded. If, at decision block 1116, it is determined that there are more unexamined layers, block 1114 is iterated until all layers have been examined, their CD calculated and recorded. If, at decision block 1116 it is determined that all copper layers have been examined and their CD calculated, the routine moves to block 1118.

In block 1118, the first unexamined electronic component listed in the PCB's BOM is analyzed for various characteristics. Such characteristics may be readily available from computerized linkage to electronic component vendors, or from data aggregators that assemble such information into an industry standard database. Commonly available characteristics of electronic components may include physical dimensions, packaging type and packaging specifications. Such characteristics are recorded for later use. The routine moves to decision block 1120.

If, at decision block 1120, it is determined that the BOM item is packaged using tape and reel, the routine moves to block 1122. If the BOM item is not packaged in tape and reel, the routine moves to decision block 1124.

If, at decision block 1124, it is determined that the BOM item is packaged using trays, the routine moves to block 1126. If the BOM item is not packaged in trays, the routine moves to decision block 1128.

If, at decision block 1128, it is determined that the BOM item is packaged using tubes, the routine moves to block 1130. In one or more of the disclosed embodiments, only components packaged in Reel and Tape, Trays and Tubes may be considered, but other packaging types (for example, but not limited to, Cut Tape and Loose Components) may be supported in alternate embodiments. If the BOM item is not packaged in tubes, the routine moves to decision block 1132.

If, at decision block 1132, it is determined that the BOM item is packaged using cut tape segments, the routine moves to block 1134, otherwise the routine moves to block 1136.

In block 1122, the Component Reel Space Requirement of the BOM item is calculated and as with all other data and characteristics, recorded and associated with the PCB design files, in this case, the PCB BOM. Likewise, in block 1126, the Component Tray Capacity of the BOM item is recorded and associated with the PCB BOM. Likewise, in block 1130, the Component Tube Capacity of the BOM item is recorded and associated with the PCB BOM. Likewise, in block 1134, Component Tray Space Requirement of the BOM item is calculated and is recorded and associated with the PCB BOM. After blocks 1122, 1126, 1130 or 1134, the routine moves to decision block 1136.

If, at decision block 1136, it is determined that there are more unexamined BOM electronic component listings, the routine moves back to block 1118 and the previously described operational blocks are reiterated until all BOM listings have been examined. Eventually, the routine moves to block 1138. At block 1138, the PCB design files and associated data and characteristics are marked as Pending. Pending status signifies that the submitted PCB design is awaiting another process before being placed on a PCB panel.

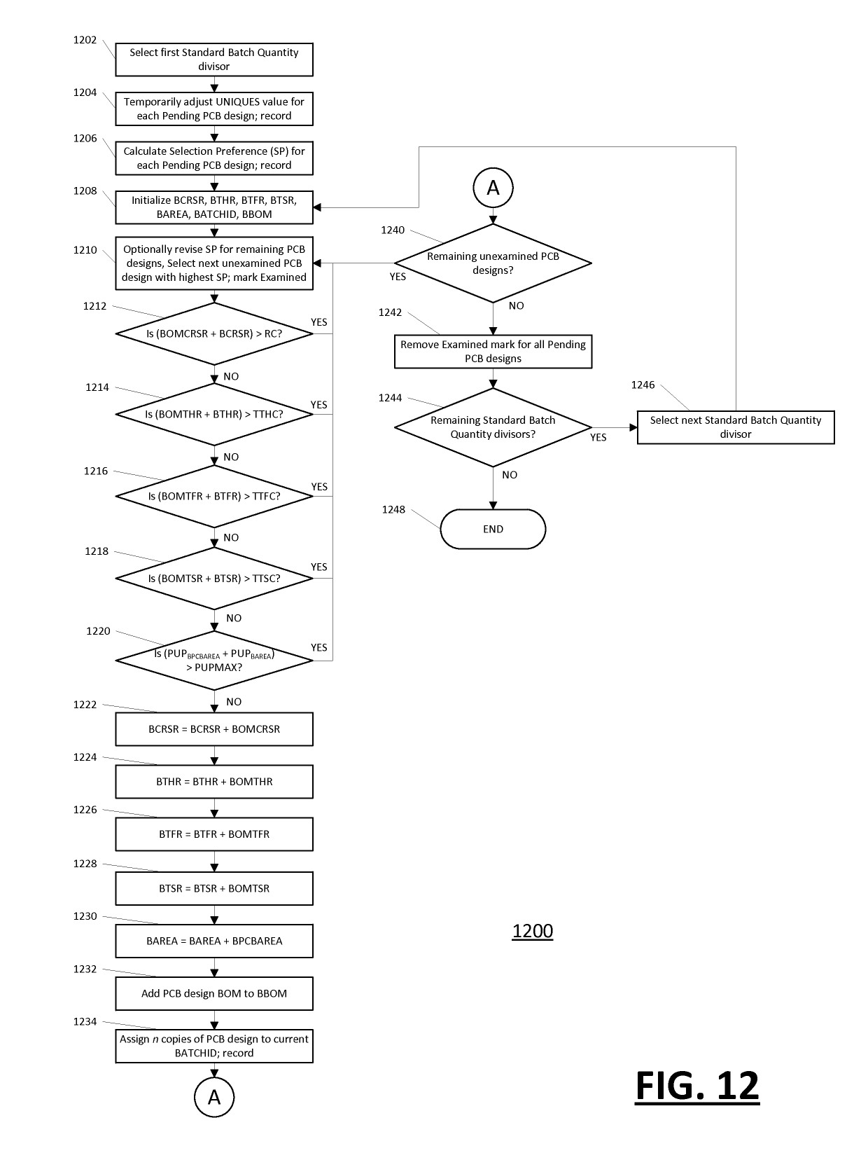

Referring now to FIG. 12, there is shown a flowchart generally representing an exemplary process of the disclosed embodiments. The sample process 1200 highlights some of the operations for creating production batch candidates of Pending PCB designs that have been processed in accordance with sample process 1100.

In addition to the data required, collected and calculated in sample process 1100, other data and characteristics may be utilized for sample process 1200. Such data and characteristics may include:
Intended PCB panel dimensions, namely, as previously detailed, PW, PL, PBW1, PBW2, PBL1 and PBL2 of a given panel type.
PCB design physical dimensions (BW, BL), recorded at block 1110 of sample process 1100.
Acceptable Maximum Panel Utilization Percentage or “PUPMAX”.
As previously detailed, PCBA machine Reel Capacity, termed RC.
As previously detailed, PCBA machine Total Tray Holder Capacity, termed TTHC.
As previously detailed, PCBA machine Total Tube Feeder Capacity, termed TTFC.
As previously detailed, PCBA machine Total Tray Space Capacity, termed TTSC.
The Standard Batch Quantity, as previously detailed.
The Previous Batch BOM (“PBBOM”). The PBBOM is the aggregate BOM for all PCB designs that are previously selected for the production batch intended for assembly immediately prior to the current batch.
The number of BOM Uniques for a given PCB design, as previously detailed (“UNIQUES”).
Elapsed time since PCB Files received based on the data recorded at block 1108 of sample process 1100 and subsequently marked Pending at block 1134 (“PENDINT”).
The set of whole integer divisors for the Standard Batch Quantity.

In block 1202, the first whole integer divisor of the Standard Batch Quantity is selected (e.g., 1). The routine moves to block 1204, where the UNIQUES value is adjusted by comparing each Pending PCB design's BOM to the PBBOM from the previous iteration of sample process 1200. If a BOM line item matches that of the previous PBBOM, the PCB design UNIQUES value may be temporarily decremented by a factor that decreases the weight of the UNIQUES value, for example a factor having a value of between 0 and 1, and the new value is recorded.

The routine moves to block 1206, where the Selection Preference (“SP”) for each PCB design is calculated and recorded. In at least one embodiment, the SP may be expressed as:

SP=(((BW×BL)/UNIQUES)×PENDINT)

however, in other embodiments, the SP be determined from one or more of the data and characteristics utilized for sample process 1200 mentioned above, other factors, for example, component density, PCB copper density, component thermal characteristics, inter and intra-batch UNIQUES, or any other characteristics of a customer order, a panel, batch of panels, an individual PCB, or a combination of PCBs, an individual component, or a combination of components of the panel, or characteristics of one or more machines used for PCBA.

The routine moves to block 1208, where several variables are initialized. They include:
The Batch Component Reel Space Requirement (“BCRSR”). The BCRSR is the sum of all CRSR values for all Unique Tape and Reel packaged components for the combined BOMs of all PCB designs assigned to a production batch. BCRSR is initialized to zero.
The Batch Tray Holder Requirement (“BTHR”). The BTHR is the number of Unique Tray packaged components for the combined BOMs of all PCB designs assigned to a production batch. BTHR is initialized to zero.
The Batch Tube Feeder Requirement (“BTFR”). The BTFR is the number of Unique Tube packaged components for the combined BOMs of all PCB designs assigned to a production batch. BTFR is initialized to zero.
The Batch Tray Space Requirement (“BTSR”). The BTSR is the number of Unique Tray Mounted components for the combined BOMs of all PCB designs assigned to a production batch. BTSR is initialized to zero.
The Batch Area (“BAREA”). The BAREA is the cumulative area, per panel, of all PCB designs assigned to a production batch across d panels, where d is a whole integer divisor of the Standard Batch Quantity, and may be expressed as:

BAREA=(((BL₁×BW₁)+(BL₂×BW₂)+(BL₃×BW₃)+ . . . (BLₙ×BWₙ)))))×(Standard Batch Quantity/d))
The Batch ID (“BATCHID”). In one or more of the disclosed embodiments, the BATCHID is initialized to a value based upon a timestamp, recorded at the start of sample process 1200, or other unique identifier for a prefix, and the current Standard Batch Quantity divisor being employed as a suffix. Thus, for example, in at least one of the disclosed embodiments, after sample process 1200 completes, where the Standard Batch Quantity=24, there would BATCHIDs named AAAA.1, AAAA.2, AAAA.3, AAAA.4, AAAA.6, AAAA.8, AAAA.12 and AAAA.24. In another embodiment, the function of the BATCHID may be realized via related database entries such that various Production Batch Candidates created with sample process 1200 may be identified as belonging to the same set, and by their respective Standard Batch Quantity divisor value.
The Batch BOM (“BBOM”). The BBOM is the aggregate BOM for all PCB designs selected for the current batch. It is initialized as an empty list.

The routine then moves to block 1210, where the SP for the remaining unexamined PCB designs may be adjusted by comparing one or more characteristics of previously selected designs with the remaining unexamined PCB designs using any of the characteristics for Selection Preference mentioned above. The unexamined PCB design with the highest SP is selected, and marked as “Examined”. Examined status signifies that the submitted PCB design has been evaluated for selection, and will not be re-evaluated until its Examined status is removed. The routine moves to decision block 1212.

In decision block 1212 the BOM Component Reel Space Requirement (“BOMCRSR”) is calculated using the data recorded at block 1122 of sample process 1100. The BOMCRSR is the sum of all CRSR values for all Unique Tape and Reel packaged components for the BOM of the current PCB design being evaluated. In this context, BOM components are considered Unique only if they do not also appear in the BBOM. If, at decision block 1212, it is determined that the sum of the BOMCRSR and the BCRSR exceeds that of the Reel Capacity of the PCBA machine to be employed for assembly operations, the routine returns to block 1210 and the next unexamined PCB design with the highest SP is selected. If, at decision block 1212, it is determined that the sum of the BOMCRSR and the BCRSR does not exceed the RC value, the routine moves to decision block 1214.

In decision block 1214 the BOM Component Tray Holder Requirement (“BOMTHR”) is calculated using the data recorded at block 1126 of sample process 1100. The BOMTHR is the sum of all Unique Tray packaged components in the BOM of the current PCB design being evaluated. In this context, BOM components are considered Unique only if they do not also appear in the BBOM. If, at decision block 1214, it is determined that the sum of the BOMTHR and the BTHR exceeds that of the Total Tray Holder Capacity of the PCBA machine to be employed for assembly operations, the routine returns to block 1210 and the next unexamined PCB design with the highest SP is selected. If, at decision block 1214, it is determined that the sum of the BOMTHR and the BTHR does not exceed the TTHC value, the routine moves to decision block 1216.

In decision block 1216 the BOM Component Tube Feeder Requirement (“BOMTFR”) is calculated using the data recorded at block 1130 of sample process 1100. The BOMTFR is the sum of all Unique Tube packaged components in the BOM of the current PCB design being evaluated. In this context, BOM components are considered Unique only if they do not also appear in the BBOM. If, at decision block 1216, it is determined that the sum of the BOMTFR and the BTFR exceeds that of the Tube Feeder Capacity of the PCBA machine to be employed for assembly operations, the routine returns to block 1210 and the next unexamined PCB design with the highest SP is selected. If, at decision block 1216, it is determined that the sum of the BOMTFR and the BTFR does not exceed the TTFC value, the routine moves to decision block 1218.

In decision block 1218 the BOM Tray Space Requirement (“BOMTSR”) is calculated using the data recorded at block 1134 of sample process 1100. The BOMTSR is the sum of all Unique mounted cut-tape packaged components in the BOM of the current PCB design being evaluated. In this context, BOM components are considered Unique only if they do not also appear in the BBOM. If, at decision block 1218, it is determined that the sum of the BOMTSR and the BTSR exceeds that of the Tray Space Capacity of the PCBA machine to be employed for assembly operations, the routine returns to block 1210 and the next unexamined PCB design with the highest SP is selected. If, at decision block 1218, it is determined that the sum of the BOMTSR and the BTSR does not exceed the TTSC value, the routine moves to decision block 1220.

In decision block 1220 the Batch PCB Area (“BPCBAREA”) is calculated using the data recorded at block 1110 of sample process 1100. The BPCBAREA is the area required for the currently evaluated PCB design on a PCB panel, for a production batch across d panels, where d is the currently selected whole integer divisor of the Standard Batch Quantity, and may be expressed as:

BPCBAREA=(BL×BW)×(Standard Batch Quantity/d)

If, at decision block 1220, it is determined the Panel Utilization Percentage of the sum of BPCBAREA and BAREA exceeds PUPMAX, the routine returns to block 1210 and the next unexamined PCB design with the highest SP is selected. If, at decision block, it is determined that the Panel Utilization Percentage of the sum of BPCBAREA and BAREA does not exceed PUPMAX, the routine moves to block 1222.

In block 1222, the BOMCRSR of the currently evaluated PCB design is added to the BCRSR. The routine moves to block 1224.

In block 1224, the BOMTHR of the currently evaluated PCB design is added to the BTHR. The routine moves to block 1226.

In block 1226, the BOMTFR of the currently evaluated PCB design is added to the BTFR. The routine moves to block 1228.

In block 1228, the BOMTSR of the currently evaluated PCB design is added to the BTSR. The routine moves to block 1230.

In block 1230, the BPCBAREA of the currently evaluated PCB design is added to the BAREA. The routine moves to block 1232.

In block 1232, the Unique BOM items of the currently evaluated PCB design are added to the BBOM. In this context, BOM components are considered Unique only if they do not appear in the BBOM. This may be expressed as the union of the BBOM and the BOM of the currently evaluated PCB design:

BBOM=BOM∪BBOM

The routine moves to block 1234, where n copies of the currently evaluated PCB design are assigned to the current BATCHID. n is expressed as:

n=Standard Batch Quantity/d

This assignment is recorded for later use. The routine then moves to decision block 1240.

In decision block 1240, it is determined whether there are any remaining unexamined PCB designs (i.e., those not marked “Examined”). If there are remaining unexamined PCB designs, the routine moves to block 1210. Thus, blocks 1210 through 1232 describe an iterative loop that examines all Pending PCB designs for inclusion in a Production Batch Candidate based upon a given divisor of the Standard Batch Quantity. If there are no unexamined Pending PCB designs, the routine moves to block 1242.

In block 1242, in preparation for another iterative loop, all Pending PCB designs have their Examined mark removed. The routine moves to decision block 1244.

In decision block 1244, it is determined whether there are remaining Standard Batch Quantity divisors (i.e., divisors in the set of whole integer divisors of the Standard Batch Quantity) that have not been employed in sample process 1200. If there are remaining untried divisors, the routine moves to block 1246. In block 1246, the next untried divisor is selected, and the routine moves to block 1208. If there are no remaining untried divisors, the routine ends at block 1248.

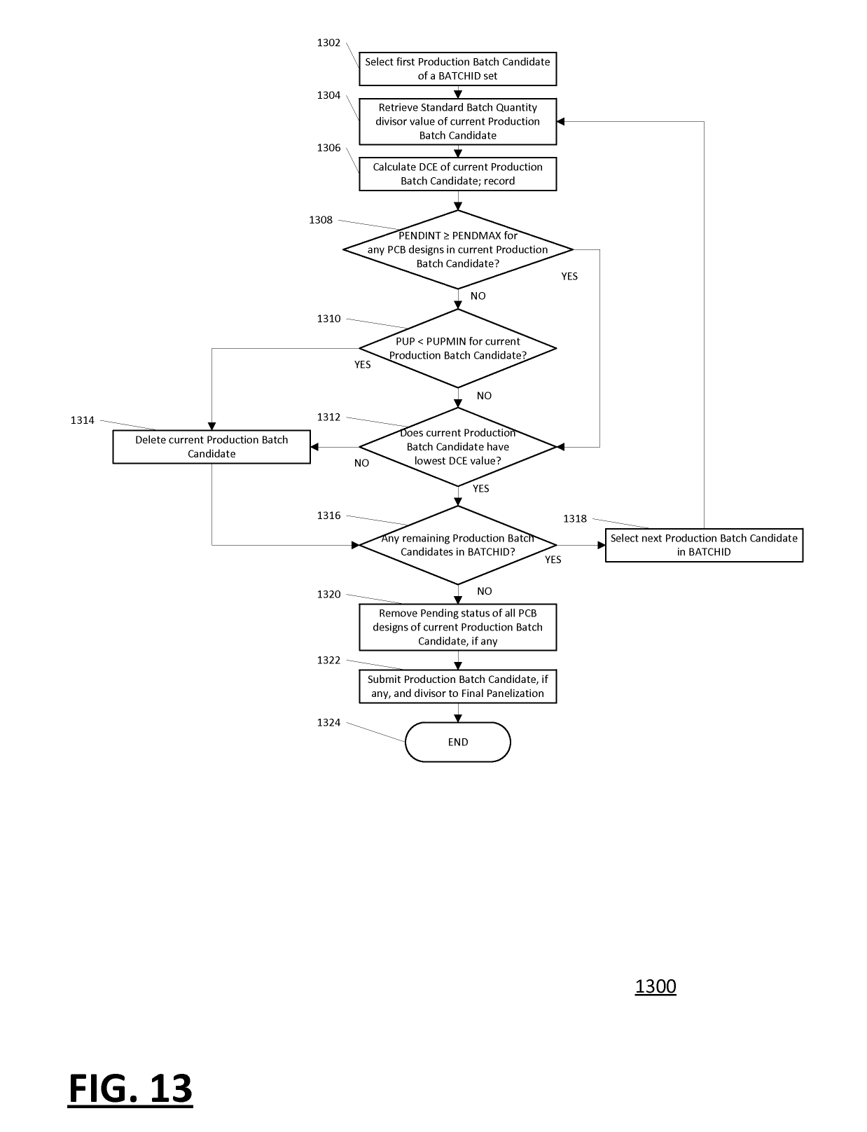

Referring now to FIG. 13, there is shown a flowchart generally representing an exemplary process of the disclosed embodiments. The sample process 1300 highlights some of the operations for selecting one of the several Production Batch Candidates of Pending PCB designs that have been processed in accordance with sample processes 1100 and 1200.

In addition to the data required, collected and calculated in sample processes 1100 and 1200, other data and characteristics are required for sample process 1300. Such data and characteristics may include:
Intended PCB panel dimensions, namely, as previously detailed, PW, PL, PBW1, PBW2, PBL1 and PBL2 of a given panel type.
PCB design physical dimensions (BW, BL), recorded at block 1110 of sample process 1100.
Panel fabrication costs; as previously detailed, the First Panel Expense, termed FPE, and Panel Copy Expense, termed PCE, of a given panel type.
A maximum Pending interval value, or “PENDMAX”, which in one or more embodiments, may trigger certain conditions in sample process 1300.
Acceptable Minimum Panel Utilization Percentage or “PUPMIN”.

In block 1302, the first Production Batch Candidate of a BATCHID set produced by sample process 1200 is selected for evaluation. The routine moves to block 1304, where the Standard Batch Quantity divisor of the Production Batch Candidate is retrieved. In some of the disclosed embodiments, the Standard Batch Quantity divisor may be retrieved by parsing a filename suffix; in another embodiment, it may be read from a database. The routine moves to block 1306.

In block 1306, the Design Cost Efficiency of the current Production Batch Candidate is calculated and recorded. As detailed earlier, the Panel Utilization Percentage is also determined as part of that calculation. The routine moves to decision block 1308.

In decision block 1308, it is determined whether any of the PCB designs in the current Production Batch Candidate have been classified as Pending for as long, or longer, than the value of PENDMAX. If one or more designs meet this condition, decision block 1310 is skipped, and the routine moves to decision block 1312. If none of the PCB designs in the current Production Batch Candidate meet this condition, the routine moves to decision block 1310.

In decision block 1310, it is determined whether the Panel Utilization Percentage of the current Production Batch Candidate is lower than the value of PUPMIN. If the current Production Batch Candidate has a lower PUP than PUPMIN, the routine moves to block 1314. If the current Production Batch Candidate has a higher PUP than PUPMIN, the routine moves to decision block 1312.

In decision block 1312, it is determined whether the current Production Batch Candidate has the lowest DCE value compared to any other Production Batch Candidates of the current BATCHID, for which this value has been calculated. If the DCE value is higher, the routine moves to block 1314. If the DCE value is lower, the routine moves to decision block 1316.

In block 1314, the current Production Batch Candidate is deleted (i.e., removed from consideration). The routine moves to decision block 1316.

In decision block 1316, it is determined whether there are any remaining unexamined Production Batch Candidates for the current BATCHID. If it is determined that there are, the routine moves to block 1318. If it is determined that there are no more unexamined Production Batch Candidates for the current BATCHID, the routine moves to block 1320.

In block 1318, the next unexamined Production Batch Candidate is selected, and the routine returns to block 1304. Blocks 1304-1318 describe an iterative loop that examines all Production Batch Candidates.

In block 1320, the Pending status of all PCB designs of the current Production Batch Candidate, if there is one, is removed, and will no longer be considered for inclusion to future Production Batch Candidates by sample process 1200. The routine moves to block 1322.

In block 1322, the Production Batch Candidate, if one has been selected, and its associated divisor value are submitted to sample process 1500 for Panelization. This Production Batch Candidate may now be termed a Production Batch Set. The routine moves to block 1324 and ends.

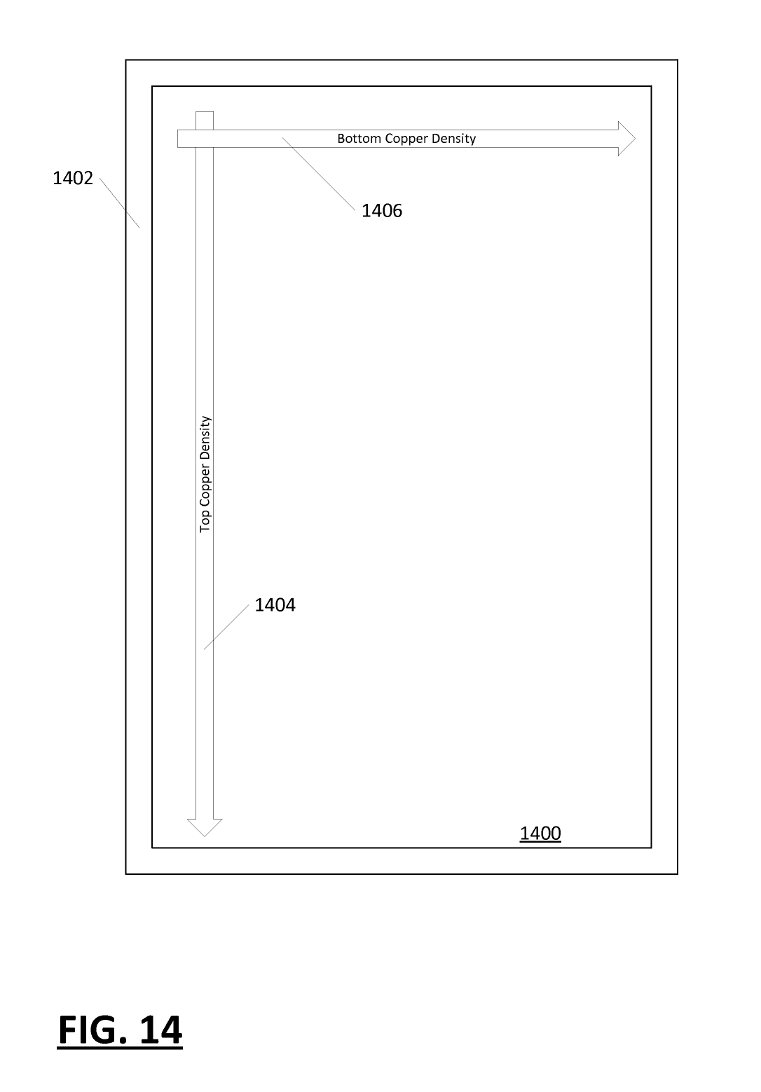

Referring now to FIG. 14, there is shown an exemplary panel with applied copper gradation scheme 1400, with a border 1402. As detailed and illustrated in FIG. 9, a PCB design may employ one or more copper layers, and those layers may have a varying Copper Density. The outer copper layers of a PCB design, as known in the art, are typically referred to as “top copper” and “bottom copper”. It may be advantageous to locate disparate PCB designs on a PCB panel in proximity based upon the Copper Densities of the top copper and bottom copper. In one or more of the disclosed embodiments, disparate PCB designs may be placed in accordance with direction 1404, wherein the PCB designs with higher top copper densities are placed towards the bottom of the panel, and with lower top copper densities, towards the top, as well in accordance with direction 1406, wherein the PCB designs with higher bottom copper densities are placed towards the right side of the panel, and with lower bottom copper densities, towards the left. In some of the disclosed embodiments, designs may be sorted such that designs with similar top and bottom copper densities are consigned to a given panel, or may be placed such that the varying copper densities are sorted according to other gradation patterns. In other aspects of the disclosed embodiments, designs may also be sorted in accordance with the previously discussed methods, but also employing the copper densities of inner layers for the sorting process.

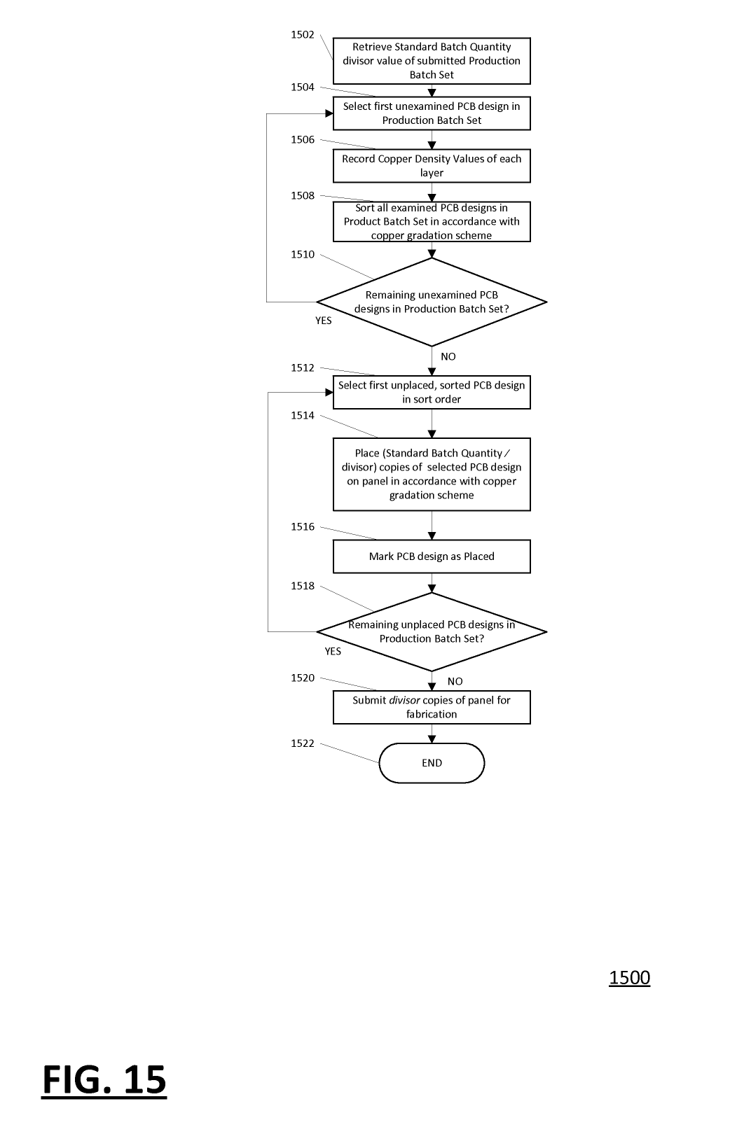

Referring now to FIG. 15, there is a shown a flowchart generally representing an exemplary process of the disclosed embodiments. The sample process 1500 highlights some of the operations for selecting PCB designs from a Production Batch Set produced by sample process 1300, and then setting the relative positioning of the designs on a PCB panel based on copper densities of the Top Copper and Bottom Copper layers. In some of the disclosed embodiments, the relative positioning of designs on a PCB panel may be based upon copper densities of multiple copper layers.

In addition to the data required, collected and calculated in sample processes 1100, 1200 and 1300 other data and characteristics are required for sample process 1500. Such data and characteristics may include:
A Copper Density Threshold Value, or “CDTV” of each copper layer, expressed as a percentage.

In block 1502, the Standard Batch Quantity divisor value of the Production Batch Set submitted by sample process 1300 is retrieved. The routine moves to block 1504, where the first unexamined PCB design in the Production Batch Set is selected. The routine moves to block 1506.

In block 1506, the Copper Density value for the Top Copper and Bottom Copper layers of the PCB design are recorded. In at least one of the disclosed embodiments, multiple copper layers may be recorded. The routine moves to block 1508.

In block 1508, all examined PCB designs are sorted such that all designs are ranked according to the copper densities of each layer, and corresponding copper gradation scheme. The routine moves to decision block 1510.

In decision block 1510, it is determined whether there are any unexamined PCB designs in the Production Batch Set. If there are, the routine returns to block 1504. If there are not, the routine proceeds to block 1512.

In block 1512, the first unplaced PCB design in sort order is selected. The routine proceeds to block 1514.

In block 1514, a number of copies equal to the Standard Batch Quantity, divided by the divisor value submitted by sample process 1300, are placed on a PCB panel in accordance with the copper gradation scheme. The PCB design copies are placed by a shape-fitting algorithm and in accordance to a pre-determined copper gradation scheme likewise corresponding to the sort order, such as the one illustrated in exemplary panel 1400. The routine moves to block 1516, where the PCB design is marked as Placed. The routine moves to decision block 1518.

In decision block 1518, it is determined whether there are remaining unplaced PCB designs in the Production Batch Set. If there are, the routine returns to block 1512, and the next unplaced PCB design in the Production Batch Set is selected. If there are no remaining unplaced PCB designs in the current Production Batch Set, the PCB panel layout is completed, and the routine moves to block 1520.

In block 1520, copies of the completed PCB panel are submitted to the PCB fabricator. The quantity of total copies is equal to the divisor value submitted by sample process 1300. The routine moves to block 1522 and terminates.

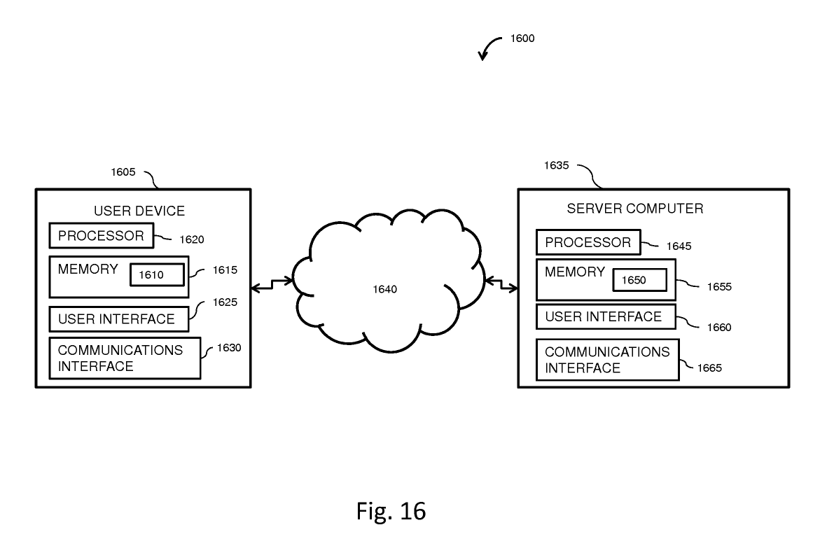

As mentioned above, the disclosed embodiments may be provided as a web service, or may be utilized in one or more stand-alone computer systems, networked computer systems, or other computing devices that are suitable for executing the disclosed panelization procedure. As such, the techniques disclosed herein may be executed by one or more computers under the control of one or more programs stored on a computer readable medium. FIG. 16 shows a block diagram of a computing system 1600 that may be used to practice aspects of the disclosed embodiments. The computing system 1600 may include at least one user terminal 1605 and at least one server computer 1610.

In an embodiment utilizing at least one stand-alone computer system, the user terminal 1605 includes computer readable program code 1610 stored on at least one computer readable medium 1615 for carrying out and executing the techniques and processes described herein. The computer readable medium 1615 may be a memory of the user terminal 1605. In alternate aspects, the computer readable program code 1610 may be stored in a memory external to, or remote from, the user terminal 1605. The memory 1615 may include magnetic media, semiconductor media, optical media, or any media which is readable and executable by a computer. User terminal 1605 may also include a microprocessor 1620 for executing the computer readable program code 1610 stored on the at least one computer readable medium 1615. In at least one aspect, the user terminal 1605 may include one or more input or output devices, generally referred to as a user interface 1625 which may operate to allow input to the user terminal 1605 or to provide output from the user terminal 1605, respectively. The user terminal 1605 may include at least one communications interface 1630 for communicating with other devices. The communications interface 1630 may be capable of communications using, for example, any wireless or wired protocol, or any suitable protocol or communications technique.

In an embodiment utilizing networked computer systems, the user terminal 1605 may communicate with a server computer 1635 through a network 1640. The server computer 1635 may include a processor 1645 for executing computer readable program code 1650 stored on at least one computer readable medium 1655 for carrying out and executing the techniques described herein. The computer readable medium 1655 may be a memory of the server computer 1635 and may include magnetic, semiconductor, or optical media, or any media which is readable and executable by a computer. A user interface 1660 may include one or more input or output devices which may operate to allow input to, or to provide output from, the serve computer 1635. The server computer 1635 may also include at least one communications interface 1665 for communicating with other devices using any suitable protocol or communications technique. The server computer 1635 may provide the user device 1605 with an interface for submitting data and for conveying the results of the procedures of the embodiments as disclosed. When the disclosed embodiments are implemented as a web-based software tool, the server computer 1635 may use the communications interface 1665 to provide the user device 1605 with web pages, for example, using HyperText Transfer Protocol (HTTP) or HTTP over Secure Sockets Layer (HTTPS) for interacting with the server computer according to the methods and procedures of the disclosed embodiments.

While the disclosed embodiments have been described with reference to one or more specific embodiments, the description is intended to be illustrative and is not to be construed as limiting. Various modifications may occur to those skilled in the art that, and while not specifically shown herein, would nevertheless be within the scope of the disclosed embodiments.

1. A method comprising:
determining a single standard batch quantity for all printed circuit boards designs to be considered for placement on one or more panels;
determining a selection preference based on at least a first characteristic for each of the printed circuit board designs;
for each printed circuit board design in order of selection preference, assigning quantities of printed circuit board designs that satisfy a second characteristic to different batches, the quantities determined by the standard batch quantity divided by each whole integer divisor; and
selecting one or more batches for panel placement according to a design cost characteristic.

2. The method of claim 1, wherein the standard batch quantity comprises a highly composite number.

3. The method of claim 1, comprising determining the first characteristic from an area, number of unique components, and an elapsed time of an order for the printed circuit board designs.

4. The method of claim 1, comprising determining the second characteristic from bill of material information for the quantity of a printed circuit board design.

5. The method of claim 1, comprising determining the second characteristic from a reel capacity of a machine for assembling the one or more panels.

6. The method of claim 1, comprising determining the second characteristic from a tray holder capacity of a machine for assembling the one or more panels.

7. The method of claim 1, comprising determining the second characteristic from a tube feeder capacity of a machine for assembling the one or more panels.

8. The method of claim 1, comprising determining the second characteristic from a tray space capacity of a machine for assembling the one or more panels.

9. The method of claim 1, comprising determining the second characteristic from a panel area occupied by the quantity of the printed circuit board design.

10. The method of claim 1, comprising determining the design cost characteristic from an average panel expense, a panel utilization percentage, and a panel area.

11. The method of claim 1, further comprising:
determining a copper density value for each layer of each printed circuit board design of the batches selected for panel placement; and
sorting the printed circuit board designs of the batches selected for panel placement according to a copper gradation scheme.

12. An apparatus comprising:
a processor;
a memory including computer program code configured to, with the processor, cause the apparatus to:
determine a single standard batch quantity for all printed circuit boards designs to be considered for placement on one or more panels;
determine a selection preference based on at least a first characteristic for each of the printed circuit board designs;
for each printed circuit board design in order of selection preference, assign quantities of printed circuit board designs that satisfy a second characteristic to different batches, the quantities determined by the standard batch quantity divided by each whole integer divisor; and
select one or more batches for panel placement according to a design cost characteristic.

13. The apparatus of claim 12, wherein the standard batch quantity comprises a highly composite number.

14. The apparatus of claim 12, wherein the first characteristic is determined from an area, number of unique components, and an elapsed time of an order for the printed circuit board designs.

15. The apparatus of claim 12, wherein the second characteristic is based on bill of material information for the quantity of a printed circuit board design.

16. The apparatus of claim 12, wherein the second characteristic is based on a reel capacity of a machine for assembling the one or more panels.

17. The apparatus of claim 12, wherein the second characteristic is based on a tray holder capacity of a machine for assembling the one or more panels.

18. The apparatus of claim 12, wherein the second characteristic is based on a tube feeder capacity of a machine for assembling the one or more panels.

19. The apparatus of claim 12, wherein the second characteristic is based on a tray space capacity of a machine for assembling the one or more panels.

20. The apparatus of claim 12, wherein the second characteristic is determined from a panel area occupied by the quantity of the printed circuit board design.

21. The apparatus of claim 12, wherein the design cost characteristic is determined from an average panel expense, a panel utilization percentage, and a panel area.

22. The apparatus of claim 12, wherein the memory including computer program code is configured to, with the processor, further cause the apparatus to:
determine a copper density value for each layer of each printed circuit board design of the batches selected for panel placement; and
sort the printed circuit board designs of the batches selected for panel placement according to a copper gradation scheme.
